(19) United States
(12) Patent Application Publication
(10) Pub. No.: US 2020/0064692 A1
(43) Pub. Date: Feb. 27, 2020

(54) LIQUID CRYSTAL DISPLAY DEVICE

(71) Applicant: Sharp Kabushiki Kaisha, Sakai City (JP)

(72) Inventors: Akira HIRAI, Sakai City (JP); Kiyoshi MINOURA, Sakai City (JP); Yasuhiro HASEBA, Sakai City (JP); Akira SAKAI, Sakai City (JP)

(21) Appl. No.: 16/546,580

(22) Filed: Aug. 21, 2019

Related U.S. Application Data
(60) Provisional application No. 62/722,281, filed on Aug. 24, 2018.

(51) Int. Cl. G02F 1/1335; H01L 51/05

(52) U.S. Cl. CPC G02F 1/133605; H01L 51/0525

(57) ABSTRACT

The present invention provides a liquid crystal display device including: a liquid crystal panel including a viewing surface side substrate, a liquid crystal layer, and a back surface side substrate; and a backlight including a reflector facing the back surface side substrate, wherein the liquid crystal panel in a plan view includes multiple pixel regions and a non-display region between the pixel regions, in the pixel regions, color filters are disposed, in the non-display region, a gate electrode layer, a source-drain electrode layer, and a semiconductor layer are disposed, the back surface side substrate includes a reflective surface facing the backlight in at least part of the non-display region, and the reflective surface is constituted by a metal material having a higher reflectance than a metal material contained in portions of the source-drain electrode layer that are connected to the semiconductor layer.

### CROSS-REFERENCE TO RELATED APPLICATIONS

The present application claims priority under 35 U.S.C. § 119 to U.S. Provisional Patent Application No. 62/722,281 filed on Aug. 24, 2018, the contents of which are incorporated herein by reference in their entirety.

### BACKGROUND OF THE INVENTION

### Field of the Invention

The present invention relates to liquid crystal display devices.

### Description of Related Art

Liquid crystal display devices are display devices that utilize a liquid crystal composition to provide display. In their typical display system, a liquid crystal panel including a liquid crystal composition sealed between a pair of substrates is irradiated with light from a backlight. Voltage is applied to the liquid crystal composition to change the alignment of liquid crystal molecules, whereby the amount of light transmitted through the liquid crystal panel is controlled. Such liquid crystal display devices have features such as thin profile, light weight, and low power consumption, and thus are used in electronic devices such as smartphones, tablet PCs, and automotive navigation systems.

As the recent development of high-speed data networks has enabled transmission and reception of high-definition video data and the like, the definition of liquid crystal panels has been increased. An increase in the definition of a liquid crystal panel increases the area of the panel occupied by the gate lines, the source lines, and the like formed on the TFT substrate, and thus tends to reduce the aperture ratio of the panel.

A reduction in the aperture ratio is directly linked to a reduction in the amount of light that can pass through the liquid crystal panel. Such a reduction in the aperture ratio thus leads to a reduction in display properties of the liquid crystal display device such as a contrast ratio. Although increasing the luminance of the backlight can compensate for the reduction in the luminance of the liquid crystal panel, it increases the power consumption of the panel. In a liquid crystal panel with a lower aperture ratio, more light from the backlight is absorbed by the gate lines, the source lines and other lines formed on the TFT substrate, leading to poor light utilization efficiency. Such poor light utilization efficiency is a fundamental cause of an increase in the panel power consumption.

In such a situation, WO 2016/080385 aims to provide a liquid crystal display device having high light utilization efficiency, high display contrast ratio, and high image quality. WO 2016/080385 discloses a liquid crystal display device including, in the order from the back surface side: a backlight unit; a color filter substrate having color filters and a black matrix; a liquid crystal layer; and a thin-film transistor substrate including thin-film transistor elements, wherein the black matrix has a reflective layer that constitutes the surface on the backlight unit side and a light-absorbing layer that constitutes the surface on the thin-film transistor substrate side.

### BRIEF SUMMARY OF THE INVENTION

As described above, conventional liquid crystal display devices have been studied for improvement of the light utilization efficiency. Such improvement is expected to contribute to improvement of white display luminance and the like.

Commonly, the source electrodes and drain electrodes, which are in contact with the semiconductor layer, contain a metal material such as Ti—Al—Ti. When Ti—Al—Ti film is used, Ti is seen when the back surface side substrate of the liquid crystal panel is observed from the backlight side. Since Ti has a light reflectance of around 37%, it provides a low light recycling effect if it reflects light toward the backlight. When the Ti on the backlight side is removed and Al, which has a reflectance of around 80%, is positioned closest to the backlight, the Al cannot be electrically connected to the semiconductor layer. There is thus room for improvement for the source and drain electrodes to increase the reflectance of light from the backlight side to increase the light recycling effect while using a material suitable for electrical connection to the semiconductor layer in the portions connected to the semiconductor layer.

The present invention was made in view of the situation in the art and aims to provide a liquid crystal display device excellent in light utilization efficiency and advantageous for improvement of white display luminance.

### Solution to Problem

(1) In one embodiment of the present invention, the liquid crystal display device includes: a liquid crystal panel including a viewing surface side substrate, a liquid crystal layer, and a back surface side substrate; and a backlight including a reflector facing the back surface side substrate, wherein the liquid crystal panel in a plan view includes multiple pixel regions and a non-display region between the pixel regions, in the pixel regions, color filters are disposed, in the non-display region, a gate electrode layer, a source-drain electrode layer, and a semiconductor layer are disposed, the back surface side substrate includes a reflective surface facing the backlight in at least part of the non-display region, and the reflective surface is constituted by a metal material having a higher reflectance than a metal material contained in portions of the source-drain electrode layer that are connected to the semiconductor layer.

(2) In an embodiment of the present invention, the liquid crystal display device includes the structure (1), and the semiconductor layer contains an oxide semiconductor.

(3) In an embodiment of the present invention, the liquid crystal display device includes the structure (2), and the oxide semiconductor contains indium, gallium, zinc, and oxygen.

(4) In an embodiment of the present invention, the liquid crystal display device includes the structure (1), (2), or (3), the back surface side substrate includes a reflective layer provided closer to the backlight than the gate electrode and the source-drain electrode layer are, the reflective surface is constituted by the reflective layer, and the reflective layer in a plan view overlaps at least one of the gate electrode layer or the source-drain electrode layer.

(5) In an embodiment of the present invention, the liquid crystal display device includes the structure (1), (2), or (3), the reflective surface is constituted by the gate electrode layer, and the gate electrode layer is disposed on the backlight side of the source-drain electrode layer to overlap the source-drain electrode layer, and is electrically isolated from the source-drain electrode layer.

(6) In an embodiment of the present invention, the liquid crystal display device includes the structure (1), (2), or (3), the reflective surface is constituted by at least the source-drain electrode layer, and in the source-drain electrode layer, the metal material contained in the portions that are connected to the semiconductor layer is different from the metal material contained in the reflective surface facing the backlight.

(7) In an embodiment of the present invention, the liquid crystal display device includes the structure (1), (2), or (3), the reflective surface is constituted by at least the source-drain electrode layer, and in portions where the source-drain electrode layer is connected to the semiconductor layer, the source-drain electrode layer is positioned closer to the backlight than the semiconductor layer is.

(8) In an embodiment of the present invention, the liquid crystal display device includes the structure (1), (2), (3), (4), (5), (6), or (7), and further includes a reflective polarizing layer between the back surface side substrate and the backlight.

(9) In an embodiment of the present invention, the liquid crystal display device includes the structure (1), (2), (3), (4), (5), (6), (7), or (8), and the reflective surface has an area of 30% or higher relative to a total area of the pixel regions and the non-display region in the back surface side substrate.

(10) In an embodiment of the present invention, the liquid crystal display device includes the structure (1), (2), (3), (4), (5), (6), (7), (8), or (9), and the reflector has a reflectance of 50% or higher.

(11) In an embodiment of the present invention, the liquid crystal display device includes the structure (1), (2), (3), (4), (5), (6), (7), (8), (9), or (10), and the reflective surface has a reflectance of 85% or higher.

(12) In an embodiment of the present invention, the liquid crystal display device includes the structure (1), (2), (3), (4), (5), (6), (7), (8), (9), (10), or (11), and the metal material constituting the reflective surface contains at least one of aluminum or silver.

The present invention can provide a liquid crystal display device excellent in light utilization efficiency and advantageous for improvement of white display luminance.

### BRIEF DESCRIPTION OF THE DRAWINGS

FIG. 1 is a schematic cross-sectional view illustrating the structure of a liquid crystal display device of Embodiment 1.

FIG. 2 is an enlarged schematic plan view of one pixel of a TFT substrate of Embodiment 1.

FIG. 3 is a schematic plan view illustrating the structure of a reflective layer 110 of Embodiment 1.

FIG. 4 is a schematic cross-sectional view illustrating the structure of the TFT substrate of Embodiment 1.

FIG. 5 illustrates a case where an Al film 135b of a source-drain electrode layer contacts a semiconductor layer 140.

FIG. 6 illustrates a case where a Ti film 135a of a source-drain electrode layer contacts the semiconductor layer 140.

FIG. 7 is a schematic plan view illustrating the structure of a gate electrode layer 131 of Embodiment 2.

FIG. 8 is a schematic cross-sectional view illustrating the structure of a TFT substrate of Embodiment 2.

FIG. 9 is an enlarged schematic plan view of one pixel of a TFT substrate of Embodiment 3.

FIG. 10 is a schematic cross-sectional view illustrating the structure of the TFT substrate of Embodiment 3.

FIG. 11 is a schematic cross-sectional view illustrating the structure of a TFT substrate of Embodiment 4.

FIG. 12 is a schematic cross-sectional view illustrating the structure of a liquid crystal display device of Embodiment 5.

FIG. 13 is a schematic cross-sectional view illustrating the structure of a liquid crystal display device of Embodiment 6.

FIG. 14 is a schematic cross-sectional view illustrating the structure of a liquid crystal display device in which a second polarizing plate 15 is provided closer to the backlight than the reflective surface is.

FIG. 15 is a schematic cross-sectional view illustrating the structure of a liquid crystal display device prepared in Example 5.

FIG. 16 is a schematic cross-sectional view illustrating the structure of a liquid crystal display device prepared in Example 6.

FIG. 17 is a schematic cross-sectional view illustrating the structure of a liquid crystal display device prepared in Example 7.

FIG. 18 is a schematic cross-sectional view illustrating the structure of a liquid crystal display device prepared in Example 8.

FIG. 19 is a schematic cross-sectional view illustrating the structure of a liquid crystal display device prepared in Example 9.

FIG. 20 is a schematic cross-sectional view illustrating the structure of a liquid crystal display device prepared in Example 10.

FIG. 21 is a schematic cross-sectional view illustrating the structure of a liquid crystal display device prepared in Example 11.

FIG. 22 is a schematic cross-sectional view illustrating the structure of a liquid crystal display device prepared in Example 12.

### DETAILED DESCRIPTION OF THE INVENTION

### Definitions of Terms

The “viewing surface side” as used herein means the side closer to the screen (display surface) of the liquid crystal display device. The “back surface side” means the side farther from the screen (display surface) of the liquid crystal display device.

Hereinafter, embodiments of the present invention will be described. The following embodiments are not intended to limit the scope of the present invention. Appropriate modifications can be made within the spirit of the present invention.

### Embodiment 1

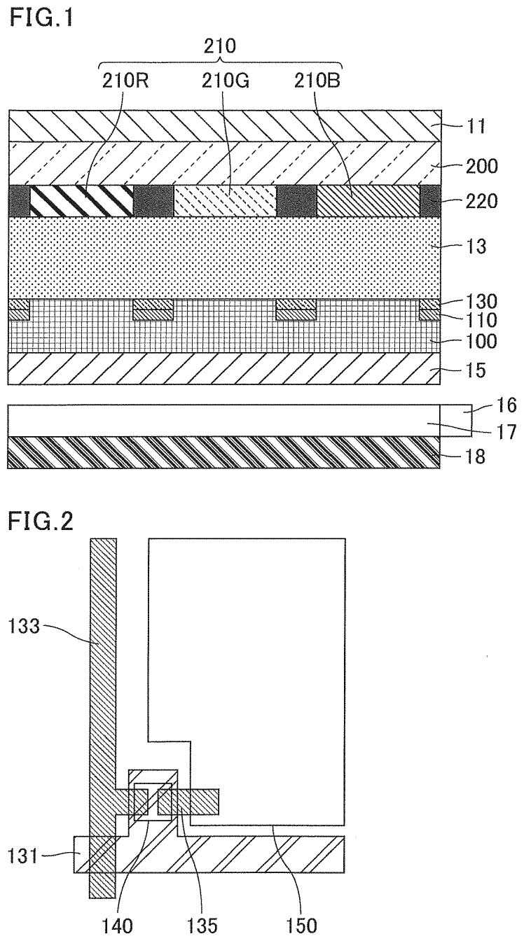

FIG. 1 is a schematic cross-sectional view illustrating the structure of a liquid crystal display device of Embodiment 1. As illustrated in FIG. 1, the liquid crystal display device of this embodiment includes a liquid crystal panel. The liquid crystal panel includes, in the order from the viewing surface side; a first polarizing plate 11; a color filter substrate (viewing surface side substrate) including a transparent substrate 200, a color filter (CF) layer 210, and a black matrix layer 220; a liquid crystal layer 13; a thin-film transistor substrate (back surface side substrate) including a transparent substrate 100, a reflective layer 110, and a line electrode layer 130; and a second polarizing plate 15. The color filter substrate and the thin-film transistor substrate are bonded to each other with a sealant surrounding the periphery of the liquid crystal layer 13. The liquid crystal layer 13 is held between the substrates.

A backlight is provided on the back surface side of the liquid crystal panel. The backlight emits light, and the amount of light that passes through the liquid crystal display panel is controlled by voltage applied to the liquid crystal layer 13 in the liquid crystal panel. Although FIG. 1 illustrates an edge-lit backlight including a light source 16, a light guide plate 17, and a reflector 18, the backlight of this embodiment may be of any type and may be a direct-lit backlight. The light source 16 of the backlight may be of any type. Examples thereof include light-emitting diodes (LEDs) and cold cathode fluorescent lamps (CCFLs). The reflector 18 is disposed on the back surface side of the light guide plate 17 and faces the thin-film transistor substrate. The reflector 18 may be formed of any material that can reflect light incident from the light guide plate 17 side. From the standpoint of a sufficient increase in the light recycling effect, the reflector 18 preferably has a reflectance of 50% or higher.

The first polarizing plate 11 and the second polarizing plate 15 provided in the liquid crystal display panel are preferably absorptive polarizing plates obtained by aligning an anisotropic material such as a dichroic iodine complex adsorbed onto a polyvinyl alcohol (PVA) film. Typically, each surface of the PVA film is laminated with a protective film such as a triacetyl cellulose film for practical use. An optical film such as a retardation film may be disposed between the first polarizing plate 11 and the transparent substrate 200 and between the transparent substrate 100 and the second polarizing plate 15.

The polarization axis of the first polarizing plate 11 and the polarization axis of the second polarizing plate 15 may be orthogonal to each to other. The polarization axis may be an absorption axis or a transmission axis of the polarizing plate.

The color filter substrate (CF substrate) includes the color filter (CF) layer 210, the black matrix layer 220, a counter electrode, and the like on the surface of the transparent substrate 200 (e.g., glass substrate). The color filter substrate may be a color filter substrate usually used in the field of the liquid crystal panel. The liquid crystal panel of this embodiment in a plan view includes multiple pixel regions and a non-display region between the pixel regions. In the pixel regions, the color filter (CF) layer 210 is disposed. In the non-display region between the pixel regions, the black matrix layer 220 is disposed. The color filters provided in the color filter layer 210 may have any color. The color filter layer 210 may contain, for example, a red (R) color filter 210R, a green (G) color filter 210G, and a blue (B) color filter 210B.

The liquid crystal layer 13 contains liquid crystal. Alignment films (not shown) to control the alignment of liquid crystal molecules are disposed on the surfaces holding the liquid crystal layer 13 therebetween. The liquid crystal display mode is not limited. The liquid crystal layer 13 can be applied to, for example, transverse electric field modes such as the in-plane switching (IPS) mode and the fringe field switching (FFS) mode, the vertical alignment (VA) mode, and the twisted nematic (TN) mode. In the transverse electric field modes, when no voltage is applied between the pair of electrodes (with no voltage applied) in the TFT substrate, the liquid crystal molecules in the liquid crystal layer 13 are horizontally aligned by the control force of the horizontal alignment films. In contrast, when voltage is applied between the pair of electrodes (with voltage applied), the liquid crystal molecules rotate in an in-plane direction in response to the transverse electric fields generated in the liquid crystal layer 13.

The thin-film transistor (TFT) substrate includes the reflective layer 110, the line electrode layer 130, pixel electrodes, and the like on the surface of the transparent substrate 100 (e.g., glass substrate). In this embodiment, the reflective layer 110 including a reflective surface facing the backlight is formed on the backlight side (back surface side) of the line electrode layer 130. The line electrode layer 130 includes the terminals (gate, source, and drain) of the TFTs formed on the TFT substrate and lines electrically connected to the terminals. The line electrode layer 130 is constituted by a metal material (metal or alloy).

FIG. 2 is an enlarged schematic plan view of one pixel of the TFT substrate of Embodiment 1. The luminance of each pixel of the liquid crystal panel is controlled by controlling voltage applied to the corresponding pixel electrode 150. Each pixel electrode 150 is electrically connected to a drain electrode layer 135. The drain electrode layer 135 is connected to a source electrode layer 133 via a semiconductor layer (channel) 140. The current flowing through the semiconductor layer 140 is controlled by voltage applied to the gate electrode layer 131. The gate electrode layer 131, the source electrode layer 133, and the drain electrode layer 135 are included in the line electrode layer 130 shown in FIG. 1. The source electrode layer 133 and the drain electrode layer 135 may also be collectively referred to as a “source-drain electrode layer”. The liquid crystal panel of this embodiment in a plan view includes the pixel regions and the non-display region between the pixel regions. In the pixel regions, the pixel electrodes 150 are disposed. In the non-display region between the pixel regions, the gate electrode layer 131, the source electrode layer 133, the drain electrode layer 135, and the semiconductor layer 140 are disposed.

Suitable materials for the semiconductor layer 140 are oxide semiconductors. Examples of usable oxide semiconductors include compounds constituted by indium (In), gallium (Ga), zinc (Zn), and oxygen (O) (In—Ga—Zn—O), compounds constituted by indium (In), tin (Tin), zinc (Zn), and oxygen (O) (In-Tin-Zn—O), and compounds constituted by indium (In), aluminum (Al), zinc (Zn), and oxygen (O) (In—Al—Zn—O). Suitable among them are compounds containing indium, gallium, zinc, and oxygen (IGZO).

The pixel electrodes 150 may be transparent electrodes. For example, the pixel electrodes may be formed from a transparent conductive material such as indium tin oxide (ITO), indium zinc oxide (IZO), zinc oxide (ZnO), or tin oxide (SnO), or an alloy of any of them.

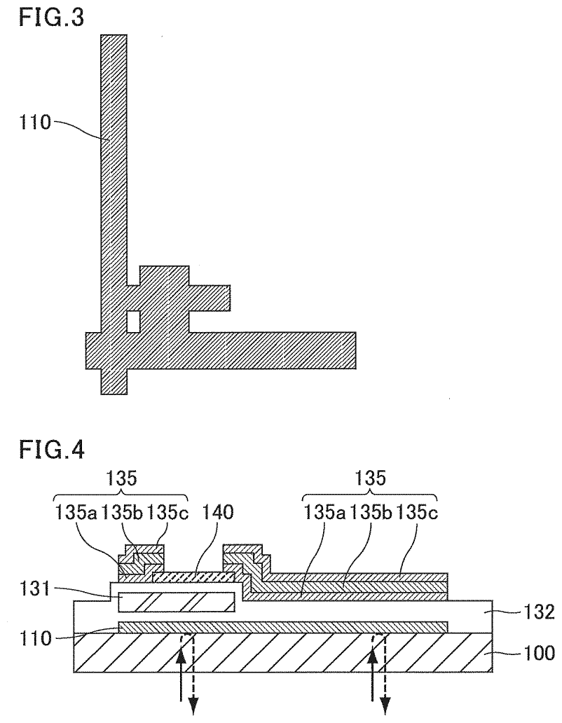

FIG. 3 is a schematic plan view illustrating the structure of the reflective layer 110 of Embodiment 1. As illustrated in FIG. 3, the reflective layer 110 corresponds to the gate electrode layer 131, the source electrode layer 133, and the drain electrode layer 135. The reflective layer 110 includes a reflective surface facing the backlight, and thus can efficiently reflect light to be incident on the gate electrode layer 131, the source electrode layer 133, and the drain electrode layer 135.

FIG. 4 is a schematic cross-sectional view illustrating the structure of the TFT substrate of Embodiment 1. Each solid arrow in FIG. 4 represents the optical path and travel direction of light traveling toward the reflective layer 110. Each dotted arrow in FIG. 4 represents the optical path and the travel direction when the light is reflected by the reflective layer 110. The TFT substrate has a structure in which the gate electrode layer 131, the gate insulator 132, the semiconductor layer 140, and the drain electrode layer 135 are stacked on the transparent substrate 100.

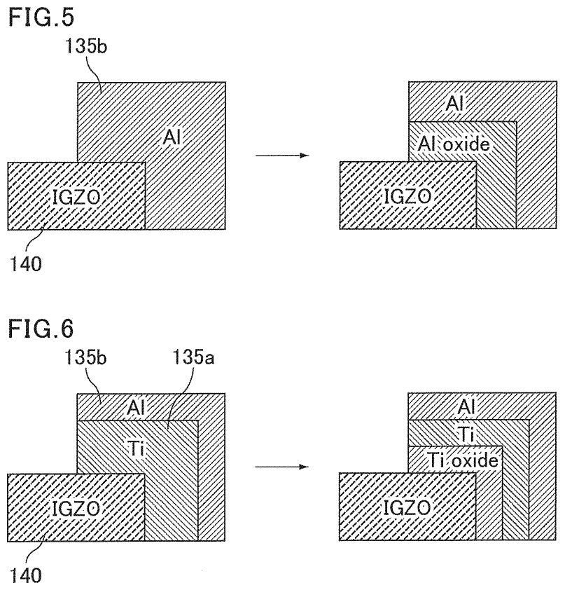

The reflective surface formed by the reflective layer 110 is constituted by a metal material having a higher reflectance than a metal material contained in the portions of the source-drain electrode layer that are connected to the semiconductor layer 140. The source-drain electrode layer is suitably a stack of a Ti film 135a, an Al film 135b, and a Ti film 135c. Since Ti, having a reflectance of around 37%, is insufficient for increasing the light recycling effect, Al, having a reflectance of around 80%, is preferably used in the reflective surface. It is thus desired to remove the Ti film 135a on the transparent substrate 100 side to form a stack of the Al film 135b and the Ti film 135c. In this case, however, as illustrated in FIG. 5, the Al film 135b of the source-drain electrode layer contacts the oxide semiconductor (e.g., IGZO) of the semiconductor layer 140. As a result, the oxygen in the oxide semiconductor reacts with the Al to form aluminum oxide, making it impossible to ensure conductivity. In contrast, as illustrated in FIG. 6, Ti provided between Al and the oxide semiconductor forms titanium oxide. Since titanium oxide is an n-type semiconductor, conductivity can be ensured. In this embodiment, thus, the reflective layer 110 constituted by a metal material having high reflectance such as Al is formed on the transparent substrate 100 side while the contact of the Ti film 135a of the source-drain electrode layer with the oxide semiconductor is maintained.

The reflective surface preferably has an area of 30% or higher relative to the total area of the pixel regions and the non-display region in the TFT substrate (back surface side substrate). Such a reflective surface can sufficiently increase the light recycling effect. The “non-display region” means a region positioned between the pixel regions, and does not include the frame region positioned at the outer edge of the TFT substrate.

The reflective surface preferably has a reflectance of 85% or higher. Such a reflective surface can sufficiently increase the light recycling effect. The metal material constituting the reflective surface preferably contains at least one of aluminum (Al) or silver (Ag).

Embodiment 1 preferably has the following features.

(1-1) The reflective layer 110 including a reflective surface facing the backlight is disposed closer to the transparent substrate 100 (to the backlight) than the gate electrode layer 131, the source electrode layer 133, and the drain electrode layer 135 are.
(1-2) The semiconductor layer 140 contains an oxide semiconductor. The oxide semiconductor is preferably one containing indium, gallium, zinc, and oxygen (IGZO).
(1-3) The reflective layer 110 in a plan view overlaps at least one of the gate electrode layer 131, the source electrode layer 133, or the drain electrode layer 135. The reflective layer 110 in a plan view more preferably overlaps two of the gate electrode layer 131, the source electrode layer 133, and the drain electrode layer 135, still more preferably overlaps all of the gate electrode layer 131, the source electrode layer 133, and the drain electrode layer 135.
(1-4) The reflective layer 110 is electrically isolated from the gate electrode layer 131, the source electrode layer 133, and the drain electrode layer 135.
(1-5) The source electrode layer 133 and the drain electrode layer 135 are each a multilayer film including a Ti layer, an Al layer, and a Ti layer in the stated order (Ti—Al—Ti).

The light recycling effect can be obtained by efficient reflection of light between the reflective layer 110 disposed in the CF substrate and the reflector 18 of the backlight. Thus, the higher the reflectance of the reflective layer 110, and the higher the reflectance of the reflector 18 of the backlight, the better. The material of the reflective layer 110 may be Al having a reflectance of 85% or a high reflectance material such as an alloy of Ag and Al or an alloy of Ag.

The reflective layer 110 in Embodiment 1 overlaps the gate electrode layer 131, the source electrode layer 133, and the drain electrode layer 135. However, as long as the reflective layer 110 overlaps at least one of the gate electrode layer 131, the source electrode layer 133, or the drain electrode layer 135, the reflective layer 110 can exhibit the effect of efficiently reflecting light to be incident on the electrode it overlaps.

### Embodiment 2

In the present invention, the reflective surface facing the backlight may be constituted by the gate electrode layer 131 constituted by a high reflectance material such as Al. In this case, the gate electrode layer 131 is disposed on the transparent substrate 100 side (backlight side) of the source electrode layer 133 and the drain electrode layer 135 to overlap the source electrode layer 133 and the drain electrode layer 135, and is electrically isolated from the source electrode layer 133 and the drain electrode layer 135.

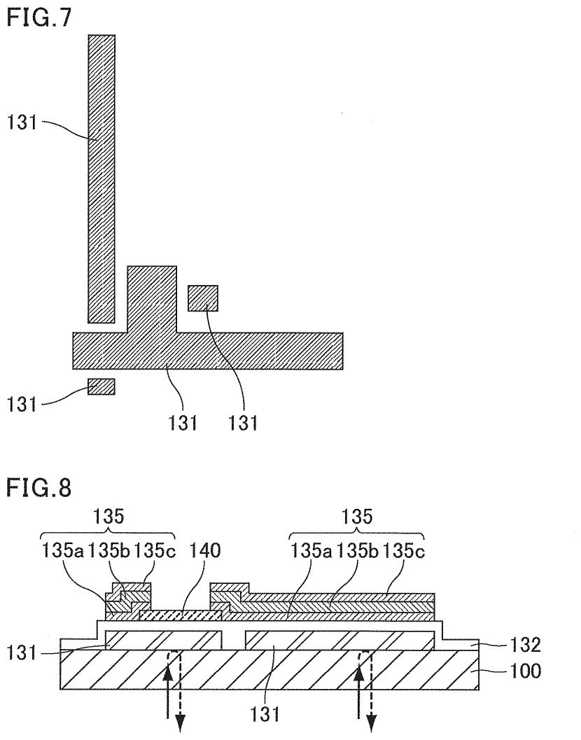

FIG. 7 is a schematic plan view illustrating the structure of the gate electrode layer 131 of Embodiment 2. As illustrated in FIG. 7, the gate electrode layer 131 is preferably formed in a pattern that includes gaps between the gate terminal portion of the TFT and the regions in which the source electrode layer 133 and the drain electrode layer 135 are disposed, so as to avoid an electrical contact of the gate terminal portion of the TFT with the source electrode layer 133 and the drain electrode layer 135.

FIG. 8 is a schematic cross-sectional view illustrating the structure of the TFT substrate of Embodiment 2. Each solid arrow in FIG. 8 represents the optical path and travel direction of light travelling toward the gate electrode layer 131. Each dotted arrow in FIG. 8 represents the optical path and the travel direction when the light is reflected by the gate electrode layer 131.

Embodiment 2 preferably has the following features.

(2-1) The gate electrode layer 131 is constituted by a high reflectance material such as Al. The gate electrode layer 131 has a portion which functions as a reflective layer including a reflective surface facing the backlight and which is positioned closer to the transparent substrate 100 (to the backlight) than the source electrode layer 133 and the drain electrode layer 135 are.
(2-2) The semiconductor layer 140 contains an oxide semiconductor. The oxide semiconductor is preferably one containing indium, gallium, zinc, and oxygen (IGZO).
(2-3) The gate electrode layer 131 in a plan view overlaps at least one of the source electrode layer 133 or the drain electrode layer 135. The gate electrode layer 131 in a plan view more preferably overlaps both the source electrode layer 133 and the drain electrode layer 135.
(2-4) The gate terminal portion of the TFT is electrically isolated from the portions of the gate electrode layer 131 that overlap the source electrode layer 133 and the drain electrode layer 135.
(2-5) The portions of the gate electrode layer 131 that overlap the source electrode layer 133 and the drain electrode layer 135 are electrically isolated from the source electrode layer 133 and the drain electrode layer 135.
(2-6) The source electrode layer 133 and the drain electrode layer 135 are each a multilayer film including a Ti layer, an Al layer, and a Ti layer in the stated order (Ti—Al—Ti).
(2-7) The portions of the gate electrode layer 131 that overlap the source electrode layer 133 may be electrically connected to the source electrode layer 133 as long as the portions are electrically isolated from the gate terminal portion of the TFT.
(2-8) The portions of the gate electrode layer 131 that overlap the drain electrode layer 135 may be electrically connected to the drain electrode layer 135 as long as the portions are electrically isolated from the gate terminal portion of the TFT.

### Embodiment 3

In the present invention, the reflective surface facing the backlight may be constituted by at least the source electrode layer 133 and the drain electrode layer 135. For example, the reflective surface may be constituted by the gate electrode layer 131, the source electrode layer 133, and the drain electrode layer 135. In Embodiment 3, the surface of each of the source electrode layer 133 and the drain electrode layer 135 on the transparent substrate 100 side (backlight side) is constituted by a high reflectance material such as Al. Thus, in the source electrode layer 133 and the drain electrode layer 135, the metal material contained in the portions connected to the semiconductor layer 140 is different from the metal material contained in the reflective surface.

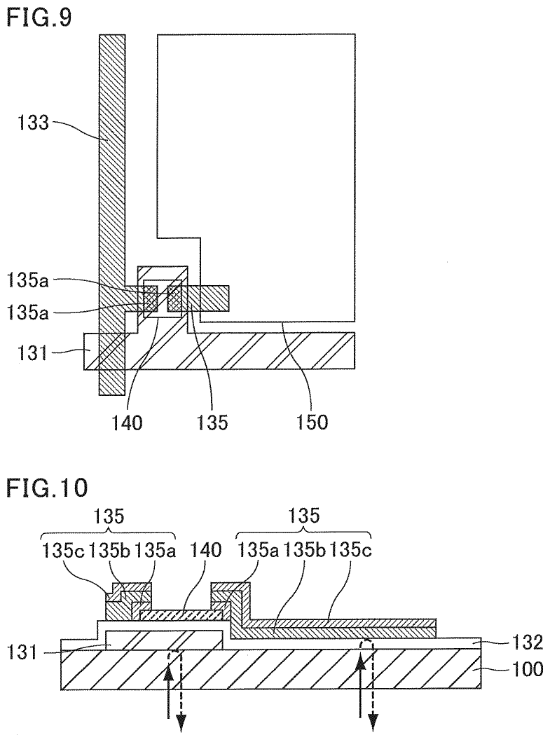

FIG. 9 is an enlarged schematic plan view of one pixel of the TFT substrate of Embodiment 3. FIG. 10 is a schematic cross-sectional view illustrating the structure of the TFT substrate of Embodiment 3. Each solid arrow in FIG. 10 represents the optical path and travel direction of light traveling toward the gate electrode layer 131, the source electrode layer 133, and the drain electrode layer 135. Each dotted arrow in FIG. 10 represents the optical path and the travel direction when the light is reflected by the gate electrode layer 131, the source electrode layer 133, and the drain electrode layer 135. As illustrated in FIGS. 9 and 10, in the source electrode layer 133 and the drain electrode layer 135, the portions connected to the semiconductor layer 140 is constituted by the Ti film 135a, while the reflective surface is constituted by the Al film 135b.

Embodiment 3 preferably has the following features.

(3-1) The source electrode layer 133 and the drain electrode layer 135 have the Ti film 135a only in the regions in contact with the semiconductor layer 140. The surface of each of the source electrode layer 133 and the drain electrode layer 135 on the transparent substrate 100 side (backlight side) is constituted by a high reflectance material such as Al.
(3-2) The semiconductor layer 140 contains an oxide semiconductor. The oxide semiconductor is preferably one containing indium, gallium, zinc, and oxygen (IGZO).
(3-3) The reflective surface is formed by at least the source electrode layer 133 and the drain electrode layer 135. The reflective surface is more preferably constituted by all of the gate electrode layer 131, the source electrode layer 133, and the drain electrode layer 135.

### Embodiment 4

In the present invention, the reflective surface facing the backlight may be constituted by at least the source electrode layer 133 and the drain electrode layer 135. For example, the reflective surface may be constituted by the gate electrode layer 131, the source electrode layer 133, and the drain electrode layer 135. In Embodiment 4, in the portions where the source electrode layer 133 and the drain electrode layer 135 are connected to the semiconductor layer 140, the source electrode layer 133 and the drain electrode layer 135 are positioned closer to the backlight (to the transparent substrate 100) than the semiconductor layer 140 is. This makes it possible to form the surfaces of the source electrode layer 133 and the drain electrode layer 135 on the backlight side (transparent substrate 100 side) with a high reflectance material such as Al to give a reflective surface, while forming the portions connected to the semiconductor layer 140 with a different metal material.

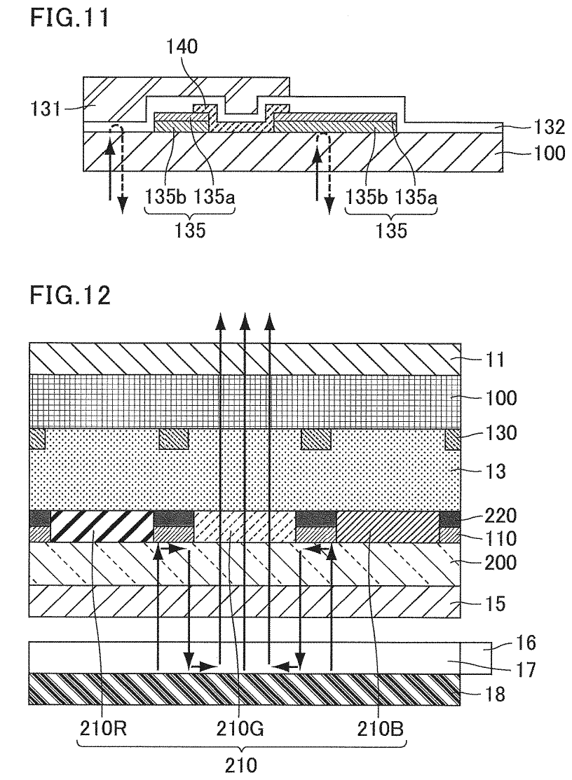

FIG. 11 is a schematic cross-sectional view illustrating the structure of the TFT substrate of Embodiment 4. Each solid arrow in FIG. 11 represents the optical path and travel direction of light traveling toward the gate electrode layer 131, the source electrode layer 133, and the drain electrode layer 135. Each dotted arrow in FIG. 11 represents the optical path and the travel direction when the light is reflected by the gate electrode layer 131, the source electrode layer 133, and the drain electrode layer 135. As illustrated in FIG. 11, in the portions where the source electrode layer 133 and the drain electrode layer 135 are connected to the semiconductor layer 140, the source electrode layer 133 and the drain electrode layer 135 are positioned closer to the transparent substrate 100 than the semiconductor layer 140 is.

Embodiment 4 preferably has the following features.

(4-1) The semiconductor layer 140 contains an oxide semiconductor. The oxide semiconductor is preferably one containing indium, gallium, zinc, and oxygen (IGZO).
(4-2) The reflective surface is formed by at least the source electrode layer 133 and the drain electrode layer 135. The reflective surface is more preferably formed by all of the gate electrode layer 131, the source electrode layer 133, and the drain electrode layer 135.

### Embodiment 5

In the present invention, the reflective surface facing the backlight in a plan view may be provided between multiple arranged color filters. FIG. 12 is a schematic cross-sectional view illustrating the structure of the liquid crystal display device of Embodiment 5. Each solid arrow in FIG. 12 represents the optical path and travel direction of light traveling toward the line electrode layer 130.

With the reflective surface provided between the color filters, light from the backlight incident on the region not used for display (region where the black matrix layer 220 is positioned) can be reflected toward the backlight side, leading to improvement of the light utilization efficiency. In this case, the reflective surface may be constituted by at least one of the gate electrode layer 131, the source electrode layer 133, or the drain electrode layer 135, or may be constituted by the reflective layer 110. The reflective layer 110 and the color filter layer 210 may be disposed on the same substrate or different substrates. Although the color filter layer 210 and the black matrix layer 220 in Embodiment 1 are disposed on the counter substrate, at least one of the color filter layer 210 or the black matrix layer 220 may be disposed on the TFT substrate.

### Embodiment 6

In the present invention, the second polarizing plate 15 on the backlight side is preferably disposed closer to the viewing surface than the reflective surface is. This structure prevents the light reflected on the reflective surface from passing through the second polarizing plate 15, and thus allows more improvement of the light utilization efficiency. From the standpoint of providing display using liquid crystal, the second polarizing plate 15 is disposed closer to the back surface than the liquid crystal layer 13 is.

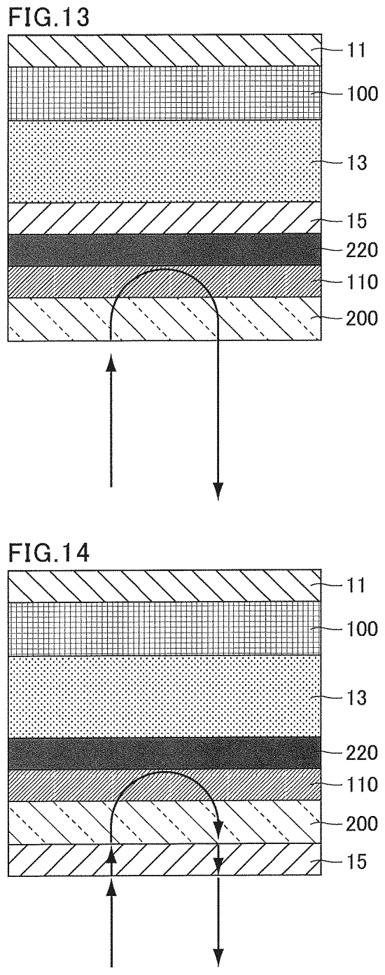

FIG. 13 is a schematic cross-sectional view illustrating the structure of the liquid crystal display device of Embodiment 6. FIG. 14 is a schematic cross-sectional view illustrating the structure of a liquid crystal display device in which the second polarizing plate 15 is disposed closer to the backlight than the reflective surface is. The liquid crystal display device of Embodiment 6 in FIG. 13 has the same structure as the liquid crystal display device in FIG. 14 except for the position of the second polarizing plate 15. Each solid arrow in FIGS. 13 and 14 represents the optical path and travel direction of light emitted from the backlight and reflected on the reflective surface.

Comparison of FIG. 13 and FIG. 14 shows that in the structure in FIG. 14, the light reflected by the reflective layer 110 passes through the first polarizing plate 15 twice, while in the structure of Embodiment 6 in FIG. 13, the light reflected by the reflective layer 110 does not pass through the second polarizing plate 15. Embodiment 6 is thus excellent in light utilization efficiency as the light reflected by the reflective layer 110 is not attenuated by absorption by the second polarizing plate 15.

The second polarizing plate 15 on the backlight side may be a reflective polarizing layer. Also in this case, the light utilization efficiency can be further improved.

The present invention will be described in more detail below with reference to examples and a comparative example. The present invention should not be limited to these examples.

### Example 1

In Example 1, the liquid crystal display device of Embodiment 1 was prepared. A TFT substrate of Example 1 was prepared by the following method.

First, aluminum (Al) was sputtered on a transparent substrate. The Al film was patterned by photolithography using a positive resist to form a reflective layer. Next, an insulating layer was disposed to allow the reflective layer to electrically float. Then, (1) a gate electrode layer made of tungsten (W), (2) a gate insulating layer, and (3) a semiconductor layer (IGZO layer) made of an oxide semiconductor containing indium, gallium, zinc, and oxygen were formed in their respective patterns. A titanium (Ti) film, an Al film, and a Ti film were then stacked in the stated order. The obtained multilayer film was patterned to form a source-drain electrode layer. As illustrated in FIG. 3, the pattern of the reflective layer corresponds to the regions where the gate electrode layer and the source-drain electrode layer are disposed. Subsequently, an interlayer insulating film, pixel electrodes, and the like were formed, whereby a TFT substrate for FFS mode including TFT elements was prepared.

Next, liquid crystal was added dropwise onto a counter substrate (CF substrate) by an ODF device, and the TFT substrate was bonded to the CF substrate to prepare a liquid crystal panel. A pair of absorptive polarizing layers was then disposed on the TFT substrate and CF substrate of the liquid crystal panel such that the polarized light transmission axes crossed each other at 90°. On the TFT substrate was then disposed a backlight having a light guide plate and a reflector. Thus, a liquid crystal display device having the structure illustrated in FIG. 1 was prepared. The backlight had a luminance of 5,000 cd/m² and a reflectance of 50%.

### Example 2

In Example 2, the liquid crystal display device of Embodiment 2 was prepared. A TFT substrate of Example 2 was prepared by the following method.

First, Al was sputtered on a transparent substrate. A gate electrode layer was formed by photolithography using a positive resist. The pattern of the gate electrode layer included the regions where the source-drain electrode layer was disposed. Here, the gate electrode layer was formed in a pattern that included gaps between the gate terminal portions and the regions where the source-drain electrode layer was disposed, so as to avoid an electrical contact with the source-drain electrode layer. The preparation of a gate insulating layer and the subsequent procedure were performed as in Example 1.

### Example 3

In Example 3, the liquid crystal display device of Embodiment 3 was prepared. A TFT substrate of Example 3 was prepared by the following method.

First, (1) a gate electrode layer made of Al, (2) a gate insulating layer, and (3) an IGZO layer were formed on a transparent substrate. Ti was then sputtered and the Ti film was patterned such that the Ti film was substantially only in the regions where the source-drain electrode layer and the IGZO layer overlapped. Thereafter, Al and Ti films were stacked in the stated order, and the obtained multilayer film was patterned to form a source-drain electrode layer. The subsequent procedure was performed as in Example 1 to prepare a TFT substrate. A liquid crystal display device was prepared as in Example 1 using the obtained TFT substrate.

### Example 4

In Example 4, the liquid crystal display device of Embodiment 4 was prepared. A TFT substrate of Example 4 was prepared by the following method.

First, an Al film and a Ti film were stacked in the stated order on a transparent substrate, and the obtained multilayer film was patterned to form a source-drain electrode layer. An IGZO layer was then formed by patterning. Next, an insulating layer was formed and a gate electrode layer was formed with Al by patterning. The subsequent procedure was performed as in Example 1 to prepare a TFT substrate. A liquid crystal display device was prepared as in Example 1 using the obtained TFT substrate.

### Comparative Example 1

(1) A gate electrode layer made of W, (2) a gate insulating layer, and (3) an IGZO layer were formed on a transparent substrate. A Ti film, an Al film, and a Ti film were then stacked in the stated order, and the obtained multilayer film was patterned to form a source-drain electrode layer. The subsequent procedure was performed as in Example 1 to prepare a TFT substrate including no reflective layer. A liquid crystal display device was prepared as in Example 1 using the obtained TFT substrate.

### (Evaluation Test 1)

The white display luminance of the liquid crystal display devices of Examples 1 to 4 and Comparative Example 1 was measured in a darkroom. The luminance was measured using a spectroradiometer “SR-UL2” available from Topcon Corporation. Table 1 shows the results.

The area of each gate electrode, the area of each source electrode, and the area of each drain electrode were the same in Examples 1 to 4 and Comparative Example 1. The percentage of area occupied by each electrode per pixel was as follows: 15% gate electrode, 7% source electrode, and 8% drain electrode.

TABLE 1

| | White display luminance | Relative to Comparative |
|---|---|---|
| | (cd/m²) | Example 1 |
| Example 1 | 365 | 1.12 |
| Example 2 | 360 | 1.11 |
| Example 3 | 360 | 1.11 |
| Example 4 | 367 | 1.13 |
| Comparative | 325 | 1.00 |
| Example 1 | | |

As shown in Table 1, the white display luminance in Examples 1 to 4 was higher than that in Comparative Example 1.

### Example 5

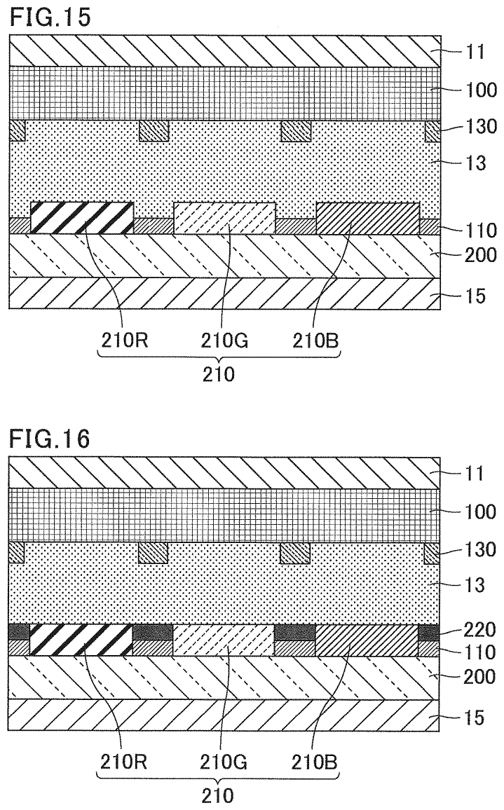

FIG. 15 is a schematic cross-sectional view illustrating the structure of a liquid crystal display device prepared in Example 5. The same TFT substrate as that of Comparative Example 1 was used. A counter substrate (CF substrate) was prepared by the following method.

First, a reflective film was formed with Al on a transparent substrate using a sputtering device. A positive resist was applied to the reflective film, and a patterned reflective layer 110 was formed by photolithography using the positive resist. The area of the patterned reflective layer 110 was the same as in Comparative Example 1. Subsequently, a color filter layer 210 and an overcoat layer were formed by photolithography, whereby a counter substrate was formed.

Next, liquid crystal was added dropwise onto the obtained counter substrate. The counter substrate was then bonded to the TFT substrate to prepare a liquid crystal panel. A pair of absorptive polarizing layers was then disposed on the TFT substrate and counter substrate of the liquid crystal panel such that the polarized light transmission axes crossed each other at 900. On the TFT substrate was then disposed a backlight having a light guide plate and a reflector. Thus, a liquid crystal display device having the structure illustrated in FIG. 15 was prepared. The backlight has a luminance of 5,000 cd/m² and a reflectance of 50%.

### Example 6

FIG. 16 is a schematic cross-sectional view illustrating the structure of a liquid crystal display device prepared in Example 6. The same TFT substrate as that of Comparative Example 1 was used. A counter substrate (CF substrate) was prepared by the following method.

First, a reflective film was formed with Al on a transparent substrate using a sputtering device. A positive resist was applied to the reflective film, and a patterned reflective layer 110 was formed by photolithography using the positive resist. Next, a negative black resist was applied, and a light-absorbing layer 220 was formed on the reflective layer 110 by photolithography to prepare a black matrix (BM). The area of the black matrix was the same as in Comparative Example 1. Subsequently, a color filter layer 210 and an overcoat layer were formed by photolithography, whereby a counter substrate was prepared. A liquid crystal display device was prepared as in Example 5 using the obtained counter substrate.

### Example 7

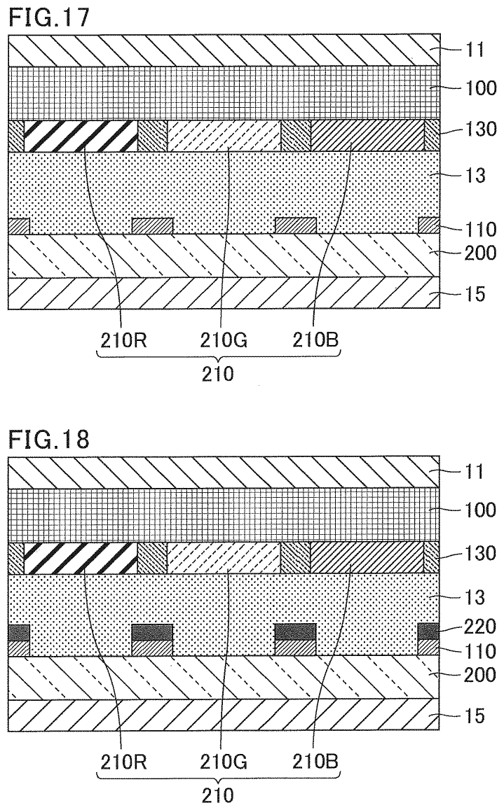

FIG. 17 is a schematic cross-sectional view illustrating the structure of a liquid crystal display device prepared in Example 7. A TFT substrate was prepared by forming a color filter layer 210 by photolithography in the TFT substrate of Comparative Example 1. A counter substrate was prepared by the following method.

First, a reflective film was formed with Al on a transparent substrate using a sputtering device. A positive resist was applied to the reflective film, and a patterned reflective layer 110 was formed by photolithography using the positive resist. The patterned reflective layer 110 was formed in the same region as the BM region that lied between color filters in the color filter-containing counter substrate of Comparative Example 1. Thus, a counter substrate was prepared. A liquid crystal display device was prepared as in Example 5 using the obtained counter substrate.

### Example 8

FIG. 18 is a schematic cross-sectional view illustrating the structure of a liquid crystal display device prepared in Example 8. A TFT substrate was prepared by forming a color filter layer 210 by photolithography in the TFT substrate of Comparative Example 1. A counter substrate was prepared by the following method.

First, a reflective film was formed with Al on a transparent substrate using a sputtering device. A positive resist was applied to the reflective film, and a patterned reflective layer 110 was formed by photolithography using the positive resist. The patterned reflective layer 110 was formed in the same region as the BM region that lied between color filters in the color filter-containing counter substrate of Comparative Example 1. Next, a negative black resist was applied, and a light-absorbing layer 220 was formed on the reflective layer 110 by photolithography, whereby a counter substrate was prepared. A liquid crystal display device was prepared as in Example 5 using the obtained counter substrate.

### Example 9

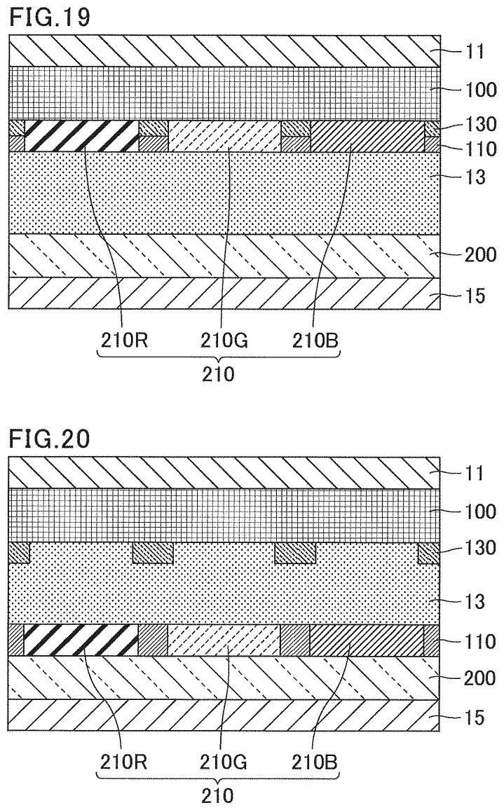

FIG. 19 is a schematic cross-sectional view illustrating the structure of a liquid crystal display device prepared in Example 9. A TFT substrate was prepared by forming a color filter layer 210 by photolithography in the TFT substrate of Comparative Example 1 and forming a patterned Al reflective layer 110 in the same regions as the regions of the gate electrode, source electrode, drain electrode, and semiconductor layer.

Next, liquid crystal was added dropwise onto a counter substrate including no color filter layer and no BM layer. The counter substrate was bonded to the TFT substrate to prepare a liquid crystal panel. A liquid crystal display device was prepared as in Example 5.

### Example 10

FIG. 20 is a schematic cross-sectional view illustrating the structure of a liquid crystal display device prepared in Example 10. A TFT substrate was prepared by changing the width of the gate lines and the source lines in the TFT substrate of Comparative Example 1 to the same width as the BM in the CF substrate of Comparative Example 1. A counter substrate was prepared by the following method.

First, a reflective film was formed with Al on a transparent substrate using a sputtering device. A positive resist was applied to the reflective film, and a patterned reflective layer 110 was formed by photolithography using the positive resist. The patterned reflective layer 110 had an area smaller than the area of the gate electrodes, the source electrodes, and the drain electrodes in the TFT substrate and was formed in a pattern invisible from the viewing surface side. Subsequently, a color filter layer 210 was formed by photolithography. A counter substrate was thus prepared. A liquid crystal display device was prepared as in Example 5 using the obtained counter substrate.

### Example 11

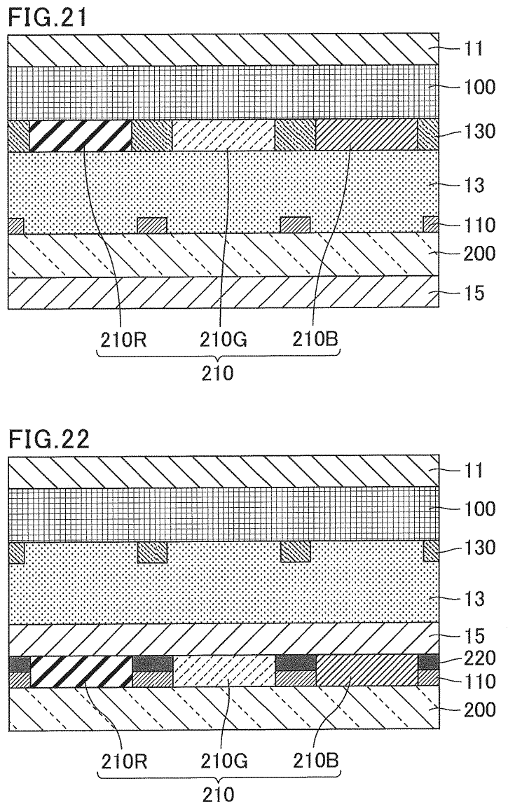

FIG. 21 is a schematic cross-sectional view illustrating the structure of a liquid crystal display device prepared in Example 11. A TFT substrate was prepared by, in the TFT substrate of Comparative Example 1, changing the width of the gate lines and the source lines to the same width as the BM in the CF substrate of Comparative Example 1 and forming a color filter layer 210 by photolithography. A counter substrate was prepared by the following method.

First, a reflective film was formed with Al on a transparent substrate using a sputtering device. A positive resist was applied to the reflective film, and a patterned reflective layer 110 was formed by photolithography using the positive resist, whereby a counter substrate was prepared. The patterned reflective layer 110 had an area smaller than the area of the gate electrodes, the source electrodes, and the drain electrodes in the TFT substrate, and was formed in a pattern invisible from the viewing surface side. A liquid crystal display device was prepared as in Example 5 using the obtained counter substrate.

### Example 12

FIG. 22 is a schematic cross-sectional view illustrating the structure of a liquid crystal display device prepared in Example 12. As illustrated in FIG. 22, the liquid crystal display device of Example 12 was the same as the liquid crystal display device of Example 6 except that an absorptive polarizing layer 15 was formed using lyotropic liquid crystal on the overcoat layer of the counter substrate (CF substrate).

### (Evaluation Test 2)

The white display luminance of the liquid crystal display devices of Examples 5 to 12 and Comparative Example 1 in a darkroom. The luminance was measured using a spectroradiometer “SR-UL2” available from Topcon Corporation. Table 2 shows the results.

TABLE 2

| | White display luminance | Relative to Comparative |
|---|---|---|
| | (cd/m²) | Example 1 |
| Example 5 | 390 | 1.20 |
| Example 6 | 390 | 1.20 |
| Example 7 | 390 | 1.20 |
| Example 8 | 390 | 1.20 |
| Example 9 | 420 | 1.29 |
| Example 10 | 367 | 1.13 |
| Example 11 | 367 | 1.13 |
| Example 12 | 406 | 1.25 |
| Comparative | 325 | 1.00 |
| Example 1 | | |

In Examples 5 to 8, the area of the reflective layer was increased compared with Examples 1 to 4 by disposing the CF substrate on the backlight side and disposing the reflective layer in the region which was originally the BM region. Thus, as shown in Table 2, the light utilization efficiency was increased and the transmittance was improved.

In Example 9, the area of the reflective layer was similar to those in Examples 1 to 4, and the light utilization efficiency was similar to those in Examples 1 to 4. However, as the aperture ratio was higher than those in Examples 1 to 4, the transmittance was greatly increased.

In Examples 10 and 11, the area of the reflective layer was similar to those in Examples 1 to 4, and thus the improving effect on white display luminance was also similar to those in Examples 1 to 4.

In Example 12, the light utilization efficiency was further increased by disposing the absorptive polarizing layer closer to the viewing surface than the reflective layer was. The transmittance was thus more improved in Example 12 than in Example 6.

In Example 6, as illustrated in FIG. 14, light from the backlight partly attenuates as it passes through the absorptive polarizing layer. After reflected by the reflective layer disposed in the CF substrate, the light again passes through the absorptive polarizing layer and thus further attenuates. The recycled light thus has a small light recycling effect.

In Example 12, as illustrated in FIG. 13, the absorptive polarizing layer is disposed closer to the viewing surface than the reflective layer disposed in the CF substrate is. The recycled light thus does not attenuate by passing through the absorptive polarizing layer, so that a sufficient light recycling effect can be obtained.

What is claimed is:

1. A liquid crystal display device comprising:
a liquid crystal panel including
a viewing surface side substrate,
a liquid crystal layer, and
a back surface side substrate; and
a backlight including a reflector facing the back surface side substrate,
wherein the liquid crystal panel in a plan view includes multiple pixel regions and a non-display region between the pixel regions,
in the pixel regions, color filters are disposed,
in the non-display region, a gate electrode layer, a source-drain electrode layer, and a semiconductor layer are disposed,
the back surface side substrate includes a reflective surface facing the backlight in at least part of the non-display region, and
the reflective surface is constituted by a metal material having a higher reflectance than a metal material contained in portions of the source-drain electrode layer that are connected to the semiconductor layer.

2. The liquid crystal display device according to claim 1,
wherein the semiconductor layer contains an oxide semiconductor.

3. The liquid crystal display device according to claim 2,
wherein the oxide semiconductor contains indium, gallium, zinc, and oxygen.

4. The liquid crystal display device according to claim 1,
wherein the back surface side substrate includes a reflective layer provided closer to the backlight than the gate electrode and the source-drain electrode layer are,
the reflective surface is constituted by the reflective layer, and
the reflective layer in a plan view overlaps at least one of the gate electrode layer or the source-drain electrode layer.

5. The liquid crystal display device according to claim 1,
wherein the reflective surface is constituted by the gate electrode layer, and
the gate electrode layer is disposed on the backlight side of the source-drain electrode layer to overlap the source-drain electrode layer, and is electrically isolated from the source-drain electrode layer.

6. The liquid crystal display device according to claim 1,
wherein the reflective surface is constituted by at least the source-drain electrode layer, and
in the source-drain electrode layer, the metal material contained in the portions that are connected to the semiconductor layer is different from the metal material contained in the reflective surface facing the backlight.

7. The liquid crystal display device according to claim 1,
wherein the reflective surface is constituted by at least the source-drain electrode layer, and
in portions where the source-drain electrode layer is connected to the semiconductor layer, the source-drain electrode layer is positioned closer to the backlight than the semiconductor layer is.

8. The liquid crystal display device according to claim 1, further including a reflective polarizing layer between the back surface side substrate and the backlight.

9. The liquid crystal display device according to claim 1,
wherein the reflective surface has an area of 30% or higher relative to a total area of the pixel regions and the non-display region in the back surface side substrate.

10. The liquid crystal display device according to claim 1,
wherein the reflector has a reflectance of 50% or higher.

11. The liquid crystal display device according to claim 1,
wherein the reflective surface has a reflectance of 85% or higher.

12. The liquid crystal display device according to claim 1,
wherein the metal material constituting the reflective surface contains at least one of aluminum or silver.
